(19) United States
(12) Patent Application Publication
(10) Pub. No.: US 2026/0271329 A1
(43) Pub. Date: Sep. 10, 2026

(54) SEMICONDUCTOR DEVICE AND MANUFACTURING METHOD THEREOF

(71) Applicant: INSTITUTE OF MICROELECTRONICS, CHINESE ACADEMY OF SCIENCES, Beijing (CN)

(72) Inventors: Yongliang LI, Beijing (CN); Xiaolei WANG, Beijing (CN)

(21) Appl. No.: 19/277,702

(22) Filed: Jul. 23, 2025

(30) Foreign Application Priority Data
Mar. 6, 2025 (CN) 202510265447.X

(51) Int. Cl. H10D 30/00; H10D 30/01

(52) U.S. Cl. CPC H10D 30/501; H10D 30/019

(57) ABSTRACT

The semiconductor device includes: a semiconductor base substrate, and a gate-all-around transistor disposed on the semiconductor base substrate, where the gate-all-around transistor includes a channel region, a source/drain region, a gate stack structure, an inner spacer, and a conductive semiconductor structure; the source/drain region is disposed on both sides of the channel region in a length direction; the gate stack structure surrounds a periphery of the channel region; the inner spacer is disposed between the gate stack structure and the source/drain region; and the conductive semiconductor structure is disposed at least between the channel region and the source/drain region, at least a partial region of the conductive semiconductor structure overlaps with at least a partial region of the inner spacer in a length direction of the gate stack structure, and there is an interface between the conductive semiconductor structure and the channel region.

### CROSS-REFERENCE TO RELATED APPLICATION

This application claims the priority of Chinese Patent Application No. 202510265447.X filed on Mar. 6, 2025 in the China National Intellectual Property Administration, the content of which is incorporated herein by reference in entirety.

### TECHNICAL FIELD

The present invention relates to a field of semiconductor technology, and in particular, to a semiconductor device and a manufacturing method thereof.

### BACKGROUND

A gate stack structure included in a gate-all-around transistor is formed not only on the top and sidewalls of at least one layer of nanostructure but also on the bottom of the at least one layer of nanostructure. Therefore, compared with a planar transistor and a fin field-effect transistor, the gate-all-around transistor has advantages such as high gate control capability. Based on this, when the transistor included in a semiconductor device adopts the gate-all-around transistor, the working performance of the semiconductor device may be improved. In addition, in practical applications, an inner spacer may be disposed between the gate stack structure and the source region, as well as between the gate stack structure and the drain region, to prevent an etchant for etching the sacrificial layer from damaging the source region and the drain region during the release of the at least one layer of nanostructure, which is beneficial for controlling the length of the gate stack structure.

However, the yield rate of the gate-all-around transistor formed by the existing manufacturing method is low, which is not conducive to improving the working performance of the gate-all-around transistor.

### SUMMARY

In a first aspect, the present invention provides a semiconductor device including: a semiconductor base substrate, and a gate-all-around transistor disposed on the semiconductor base substrate. The gate-all-around transistor includes a channel region, a source/drain region, a gate stack structure, an inner spacer, and a conductive semiconductor structure. The source/drain region is disposed on both sides of the channel region in a length direction. The gate stack structure surrounds a periphery of the channel region. The inner spacer is disposed between the gate stack structure and the source/drain region. The conductive semiconductor structure is disposed at least between the channel region and the source/drain region. At least a partial region of the conductive semiconductor structure overlaps with at least a partial region of the inner spacer in a length direction of the gate stack structure, and there is an interface between the conductive semiconductor structure and the channel region.

In an example, a conductivity type of the conductive semiconductor structure is the same as a conductivity type of the source/drain region.

In an example, a doping concentration of the conductive semiconductor structure is greater than or equal to 1 E18 cm⁻³ and less than or equal to 5 E19 cm⁻³.

In an example, a doping concentration of the conductive semiconductor structure is less than a doping concentration of the source/drain region.

In an example, a material bandgap of the conductive semiconductor structure is less than or equal to a material bandgap of the channel region.

In an example, a width of the conductive semiconductor structure disposed on both sides of the channel region in the length direction of the gate stack structure is less than a width of the inner spacer.

In an example, a sidewall of the conductive semiconductor structure disposed on both sides of the channel region facing away from the channel region is aligned with a sidewall of the inner spacer facing away from the gate stack structure.

In an example, a material of the conductive semiconductor structure is the same as a material of the channel region.

In an example, a material of the conductive semiconductor structure includes Si₁₋ₓGeₓ, and a material of the channel region includes Si_{1-y}Ge_{y}, where 0≤x≤1, 0≤y≤1, and an absolute value of a difference between x and y is less than or equal to 0.3.

In an example, the conductive semiconductor structure is further disposed between the semiconductor base substrate and the source/drain region.

In an example, in the conductive semiconductor structure disposed between the semiconductor base substrate and the source/drain region, at least a partial region in a thickness direction of the semiconductor base substrate is disposed within the semiconductor base substrate.

In an example, the gate-all-around transistor further includes a gate spacer disposed at least on both sides of the gate stack structure in a length direction; a sidewall of the channel region is recessed inward relative to a sidewall of the gate spacer in a direction in which the source/drain region approaches the channel region.

In a second aspect, the present invention provides a method of manufacturing a semiconductor device, including: first, providing a semiconductor base substrate; next, forming a fin-shaped structure on the semiconductor base substrate and forming a mask structure across the fin-shaped structure, where the fin-shaped structure includes at least one semiconductor stack, and each semiconductor stack includes a sacrificial layer and a channel layer located on the sacrificial layer; next, removing a portion of the fin-shaped structure exposed outside the mask structure; next, etching and removing edge portions on both sides of the sacrificial layer in a length direction; and forming an inner spacer on both sides of the remaining sacrificial layer; next, etching and removing edge portions on both sides of the channel layer in a length direction; next, forming a conductive semiconductor structure on both sides of the remaining channel layer; next, epitaxially forming a source/drain region; and forming a gate stack structure surrounding a periphery of the remaining channel layer to obtain a gate-all-around transistor.

In an example, the mask structure includes a sacrificial gate, and a gate spacer located on both sides of the sacrificial gate in a length direction.

In an example, a partial thickness of the semiconductor base substrate is etched while etching and removing edge portions on both sides of the channel layer in the length direction.

In an example, after forming the conductive semiconductor structure on both sides of the remaining channel layer and on the semiconductor base substrate and before the epitaxially forming a source/drain region, the method of manufacturing a semiconductor device further includes: under a protection of the mask structure, selectively etching the conductive semiconductor structure such that a sidewall of the conductive semiconductor structure disposed on both sides of the remaining channel layer facing away from the channel layer is aligned with a sidewall of the inner spacer facing away from the gate stack structure.

In an example, the forming a conductive semiconductor structure at least on both sides of the remaining channel layer includes forming the conductive semiconductor structure on both sides of the remaining channel layer and on the semiconductor base substrate.

In an example, the conductive semiconductor structure and the source/drain region are sequentially formed within a same vacuum epitaxial chamber.

### BRIEF DESCRIPTION OF THE DRAWINGS

The accompanying drawings described herein are intended to provide a further understanding of the present invention and constitute a part of the present invention, and the schematic embodiments of the present invention and the description thereof are intended to explain the present invention and are not intended to be unduly limiting the present invention, in which:

FIG. 1 shows a first schematic structural diagram of a semiconductor device during a manufacturing process according to an embodiment of the present invention;

FIG. 2 shows a second schematic structural diagram of a semiconductor device during a manufacturing process according to an embodiment of the present invention;

FIG. 3 shows a third schematic structural diagram of a semiconductor device during a manufacturing process according to an embodiment of the present invention;

FIG. 4 shows a fourth schematic structural diagram of a semiconductor device during a manufacturing process according to an embodiment of the present invention;

FIG. 5 shows a fifth schematic structural diagram of a semiconductor device during a manufacturing process according to an embodiment of the present invention;

FIG. 6 shows a sixth schematic structural diagram of a semiconductor device during a manufacturing process according to an embodiment of the present invention;

FIG. 7 shows a seventh schematic structural diagram of a semiconductor device during a manufacturing process according to an embodiment of the present invention;

FIG. 8 shows an eighth schematic structural diagram of a semiconductor device during a manufacturing process according to an embodiment of the present invention;

FIG. 9 shows a ninth schematic structural diagram of a semiconductor device during a manufacturing process according to an embodiment of the present invention;

FIG. 10 shows a tenth schematic structural diagram of a semiconductor device during a manufacturing process according to an embodiment of the present invention;

FIG. 11 shows an eleventh schematic structural diagram of a semiconductor device during a manufacturing process according to an embodiment of the present invention;

FIG. 12 shows a twelfth schematic structural diagram of a semiconductor device during a manufacturing process according to an embodiment of the present invention;

FIG. 13 shows a thirteenth schematic structural diagram of a semiconductor device during a manufacturing process according to an embodiment of the present invention;

FIG. 14 shows a fourteenth schematic structural diagram of a semiconductor device during a manufacturing process according to an embodiment of the present invention;

FIG. 15 shows a fifteenth schematic structural diagram of a semiconductor device during a manufacturing process according to an embodiment of the present invention;

FIG. 16 shows a sixteenth schematic structural diagram of a semiconductor device during a manufacturing process according to an embodiment of the present invention;

FIG. 17 shows a seventeenth schematic structural diagram of a semiconductor device during a manufacturing process according to an embodiment of the present invention;

FIG. 18 shows an eighteenth schematic structural diagram of a semiconductor device during a manufacturing process according to an embodiment of the present invention.

Reference signs: 11 is a semiconductor base substrate, 12 is a gate-all-around transistor, 13 is a channel region, 14 is a source/drain region, 15 is a gate stack structure, 16 is an inner spacer, 17 is a conductive semiconductor structure, 18 is a gate spacer, 19 is a shallow trench isolation structure, 20 is an interlayer dielectric layer, 21 is a fin-shaped structure, 22 is a mask structure, 23 is a sacrificial layer, 24 is a channel layer, and 25 is a sacrificial gate.

### DETAILED DESCRIPTION OF EMBODIMENTS

Hereinafter, embodiments of the present invention will be described with reference to the drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present invention.

Various schematic structural diagrams according to the embodiments of the present disclosure are shown in the drawings. These drawings are not drawn to scale, in which some details are enlarged and some details may be omitted for the purpose of clear expression. The shapes, the relative sizes and the positional relationships of various regions and layers shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is described to be “on” a further layer/element, the layer/element may be directly on the further layer/element, or there may be an intermediate layer/element therebetween. In addition, if a layer/element is “on” a further layer/element in one orientation, the layer/element may be “below” the further layer/element when the orientation is reversed. In order to make the technical problems to be solved, technical solutions and beneficial effects in the present invention more apparent and understandable, the present disclosure is further described in detail below in combination with the drawings and embodiments. It should be understood that the specific embodiments described herein are merely for illustration of the present invention and are not intended to limit the present invention.

In addition, terms “first” and “second” are only used for descriptive purposes and are not to be construed as indicating or implying relative importance or implicitly indicating the number of technical features indicated. Therefore, a feature defined with “first” or “second” may, explicitly or implicitly, include one or more of the feature. In the description of the present invention, “a plurality of” means two or more, unless explicitly and specifically defined otherwise. “Several” means one or more, unless explicitly and specifically defined otherwise.

In the description of the present invention, it should be noted that, unless otherwise explicitly stated or defined, terms “installed”, “connected”, and “coupled” should be interpreted broadly, and for example, they may refer to fixed connections, detachable connections, or integral connections; mechanical connections or electrical connections; direct connections, or indirect connections via intermediate media; internal communications between two elements or an interaction relationship between two elements. Those of ordinary skill in the art may understand the specific meanings of the above terms in the present invention according to specific situations.

A gate stack structure included in a gate-all-around transistor is formed not only o the top and sidewalls of at least one layer of nanostructure but also on the bottom of the at least one layer of nanostructure. Therefore, compared with a planar transistor and a fin field-effect transistor, the gate-all-around transistor has advantages such as high gate control capability. Based on this, when the transistor included in a semiconductor device adopts the gate-all-around transistor, the working performance of the semiconductor device may be improved. In addition, in practical applications, an inner spacer may be disposed between the gate stack structure and the source region, as well as between the gate stack structure and the drain region, to prevent an etchant for etching the sacrificial layer from damaging the source region and the drain region during the release of the at least one layer of nanostructure, which is beneficial for controlling the length of the gate stack structure.

However, the yield rate of the gate-all-around transistor formed by the existing manufacturing method is low. Specifically, in the actual process of manufacturing the inner spacer included in the gate-all-around transistor, in the process of etching the sacrificial layer to form a notch for filling the inner spacer, and removing the dielectric material outside the notch by selective etching after forming the dielectric material for manufacturing the inner spacer, both ends of the channel layer in the length direction are exposed. The above-mentioned etching and cleaning operations easily damage both ends of the channel layer in the length direction, resulting in a large series resistance of the connection region between the source/drain region and the channel region, which is not conducive to improving the working performance of the gate-all-around transistor.

An objective of the present invention is to provide a semiconductor device and a manufacturing method thereof, which are used for improving the formation quality of a connection region of a semiconductor material between a source/drain region and a channel region in a gate-all-around transistor, reducing the series resistance of the connection region, and improving the electrical performance of the semiconductor device.

In order to solve the above-mentioned technical problem, the embodiments of the present invention provide a semiconductor device and a manufacturing method thereof. In the semiconductor device provided by the embodiments of the present invention, a conductive semiconductor structure is at least disposed between the channel region and the source/drain region, and there is an interface between the conductive semiconductor structure and the channel region. Moreover, the conductive semiconductor structure has higher conductivity, which is beneficial for reducing the series resistance of the connection region provided between the source/drain region and the channel region and improving the electrical performance of the semiconductor device.

In a first aspect, the embodiments of the present invention provide a semiconductor device. As shown in FIG. 18, the semiconductor device includes: a semiconductor base substrate 11, and a gate-all-around transistor 12 disposed on the semiconductor base substrate 11. The gate-all-around transistor 12 includes a channel region 13, a source/drain region 14, a gate stack structure 15, an inner spacer 16, and a conductive semiconductor structure 17. The source/drain region 14 is disposed on both sides of the channel region 13 in the length direction. The gate stack structure 15 surrounds the periphery of the channel region 13. The inner spacer 16 is disposed between the gate stack structure 15 and the source/drain region 14. The conductive semiconductor structure 17 is at least disposed between the channel region 13 and the source/drain region 14. In the length direction of the gate stack structure 15, at least a partial region of the conductive semiconductor structure 17 overlaps with at least a partial region of the inner spacer 16, and there is an interface between the conductive semiconductor structure 17 and the channel region 13.

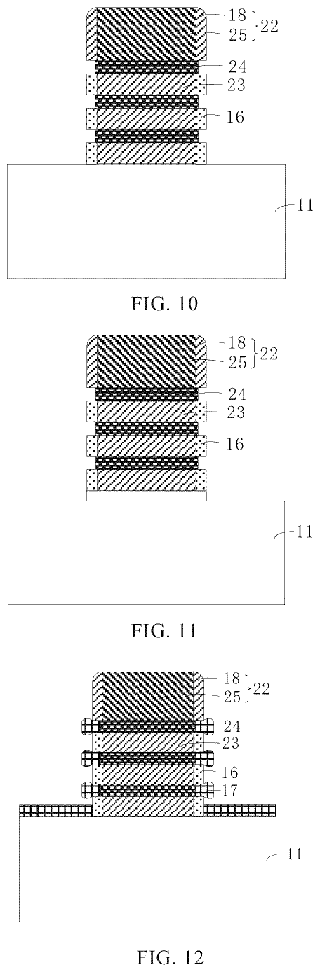

In a case of adopting the above-mentioned technical solution, as shown in FIG. 18, in the semiconductor device provided by the embodiments of the present invention, the inner spacer 16 is disposed between the gate stack structure 15 and the source/drain region 14 to limit the gate length and improve the yield rate of the gate-all-around transistor 12. Moreover, the conductive semiconductor structure 17 is further provided at least between the channel region 13 and the source/drain region 14, and there is an interface between the conductive semiconductor structure 17 and the channel region 13. Furthermore, in the length direction of the gate stack structure 15, at least the partial region of the conductive semiconductor structure 17 overlaps with at least the partial region of the inner spacer 16. Based on this, in the actual manufacturing process, as shown in FIG. 10 to FIG. 18, after forming the inner spacer 16, the edge portions on both sides of the channel layer 24 used to manufacture the channel region 13 in the length direction, which are damaged by etching in the process of forming the inner spacer 16, may be removed, and the conductive semiconductor structure 17 having higher crystal quality and conductive characteristics is formed on both sides of the remaining channel layer 24. The conductive semiconductor structure 17 also has higher conductive characteristics, which is beneficial for reducing the series resistance of the connection region provided between the source/drain region 14 and the channel region 13 and improving the electrical performance of the semiconductor device.

In practical applications, the semiconductor base substrate may be a semiconductor substrate such as a silicon substrate, a silicon-germanium substrate, a germanium substrate, or a silicon-on-insulator substrate without any structures formed thereon.

Exemplarily, the above-mentioned semiconductor base substrate may also be a semiconductor substrate with some structures formed thereon. For example, in a case that the gate-all-around transistor in the semiconductor device provided by the embodiments of the present invention is applied to the gate-all-around transistor in the second layer or a higher layer of an integrated circuit, the above-mentioned semiconductor base substrate may include a semiconductor substrate, a lower-layer device formed on the semiconductor substrate, an interlayer dielectric layer for isolating the lower-layer device, and the like.

For the gate-all-around transistor, in terms of structure, as shown in FIG. 18, the gate-all-around transistor 12 includes a channel region 13, a source/drain region 14, a gate stack structure 15, an inner spacer 16, and a conductive semiconductor structure 17.

The source/drain region is disposed on both sides of the channel region in the length direction. The materials of the source/drain region and the channel region may include any semiconductor material such as silicon, silicon-germanium, or germanium, which is not specifically limited herein. The material of the source/drain region may be the same as or different from the material of the channel region. The channel region may include only one layer of nanostructure, or, as shown in FIG. 18, the channel region 13 may also include multilayer nanostructures distributed at intervals in the thickness direction of the semiconductor base substrate 11. The number of layers of nanostructures included in the channel region 13 is not specifically limited in the embodiments of the present invention. Specifically, the materials of different layers of nanostructures included in the channel region 13 may be the same or different.

As shown in FIG. 18, the gate stack structure 15 surrounds the periphery of the channel region 13. The gate stack structure 15 may include a gate dielectric layer and a gate electrode on the gate dielectric layer. The gate dielectric layer surrounds the periphery of each layer of nanostructures included in the channel region 13 and is formed on a portion of the semiconductor base substrate 11 corresponding to the gate electrode formation region. Specifically, the material of the gate dielectric layer may be an insulating material such as HfO₂, ZrO₂, TiO₂, or Al₂O₃. The material of the above-mentioned gate electrode may be a conductive material such as TiN, TaN, or TiSiN.

In some cases, as shown in FIG. 18, the gate-all-around transistor 12 may further include a gate spacer 18 disposed at least on both sides of the gate stack structure 15 in the length direction, so as to facilitate the formation of the gate stack structure 15 and facilitate the electrical isolation of the gate stack structure 15 from adjacent other conductive structures, and reduce the risk of leakage. The material of the gate spacer 18 may include any insulating material such as silicon oxide, silicon nitride, or silicon oxynitride.

It can be understood that in a case that the gate-all-around transistor further includes the gate spacer, as shown in FIG. 18, the sidewall of the channel region 13 is recessed inward relative to the sidewall of the gate spacer 18 in the direction in which the source/drain region 14 approaches the channel region 13. In other words, after forming the inner spacer 16, an etching process is used to remove the edge portions on both sides of the channel layer 24 used to manufacture the channel region 13 in the length direction, which are damaged by etching, and the conductive semiconductor structure 17 having higher crystal quality and stronger conductivity is formed on both sides of the remaining channel layer 24 to improve the electrical performance of the gate-all-around transistor 12.

The above-mentioned inner spacer is disposed between the gate stack structure and the source/drain region. The material of the inner spacer may include any insulating material such as silicon oxide, silicon nitride, or silicon oxynitride, as long as the material may be applied to the semiconductor device provided by the embodiments of the present invention. The width of the inner spacer may be less than or equal to the width of the gate stack structure in the length direction of the gate stack structure. Alternatively, the width of the inner spacer may be slightly greater than the width of the gate stack structure to reduce the precision requirement of the etching process.

As for the above-mentioned conductive semiconductor structure, in terms of the arrangement position, the conductive semiconductor structure 17 may be only disposed between the channel region and the source/drain region. Alternatively, as shown in FIG. 18, the conductive semiconductor structure 17 may be disposed between the channel region 13 and the source/drain region 14, and between the semiconductor base substrate 11 and the source/drain region 14.

As shown in FIG. 18, the conductive semiconductor structure 17 disposed between the channel region 13 and the source/drain region 14 may be only disposed below the gate spacer 18. In this case, in the length direction of the gate stack structure 15, the width of the conductive semiconductor structure 17 disposed on both sides of the channel region 13 may be less than the width of the inner spacer 16, or may be equal to the width of the inner spacer 16. When the width of the conductive semiconductor structure 17 disposed on both sides of the channel region 13 is less than the width of the inner spacer 16, the source/drain region 14 may be prevented from being directly electrically connected to the gate stack structure 15 through the conductive semiconductor structure 17, which reduces the risk of leakage. In addition, in this case, as shown in FIG. 18, the sidewall of the conductive semiconductor structure 17 disposed on both sides of the channel region 13 facing away from the channel region 13 may be aligned with the sidewall of the inner spacer 16 facing away from the gate stack structure 15; or in the direction in which the source/drain region approaches the channel region, the sidewall of the conductive semiconductor structure disposed on both sides of the channel region facing away from the channel region may be recessed inward relative to the sidewall of the inner spacer facing away from the gate stack structure. Furthermore, in this case, the sidewall of the conductive semiconductor structure disposed on both sides of the channel region close to the channel region may be aligned with the sidewall of the inner spacer close to the gate stack structure; or the sidewall of the conductive semiconductor structure 17 disposed on both sides of the channel region 13 close to the channel region 13 may protrude outward relative to the sidewall of the inner spacer 16 close to the gate stack structure 15.

Alternatively, as shown in FIG. 12, the sidewall of the conductive semiconductor structure 17 disposed between the channel region 13 and the source/drain region 14 facing away from the channel region 13 may also protrude from the sidewall of the inner spacer 16 facing away from the gate stack structure 15. At this point, after forming the conductive semiconductor material for manufacturing the conductive semiconductor structure 17, there is no need to use a selective etching process to etch the conductive semiconductor material, which is beneficial for simplifying the manufacturing process of the semiconductor device and improving the manufacturing efficiency of the semiconductor device.

In terms of doping, the conductive type of the conductive semiconductor structure may be the same as the conductive type of the source/drain region; or the conductive type of the conductive semiconductor structure may also be the same as the conductive type of the channel region.

When the conductive type of the conductive semiconductor structure is the same as the conductive type of the source/drain region, the series resistance of the semiconductor connection region provided between the channel region and the source/drain region is favorably further reduced and the driving performance of the gate-all-around transistor is further improved.

As for the doping concentration of the conductive semiconductor structure, the doping concentration of the conductive semiconductor structure may be less than or equal to the doping concentration of the source/drain region to reduce the difficulty of doping the conductive semiconductor structure. In addition, when the doping concentration of the conductive semiconductor structure is less than the doping concentration of the source/drain region, the risk of leakage between the source region and the drain region may be further reduced.

As for the specific doping concentration of the conductive semiconductor structure, the specific doping concentration may be set according to actual needs, and is not specifically limited here. Exemplarily, the doping concentration of the conductive semiconductor structure may be greater than or equal to 1 E18 cm⁻³ and less than or equal to 5 E19 cm⁻³.

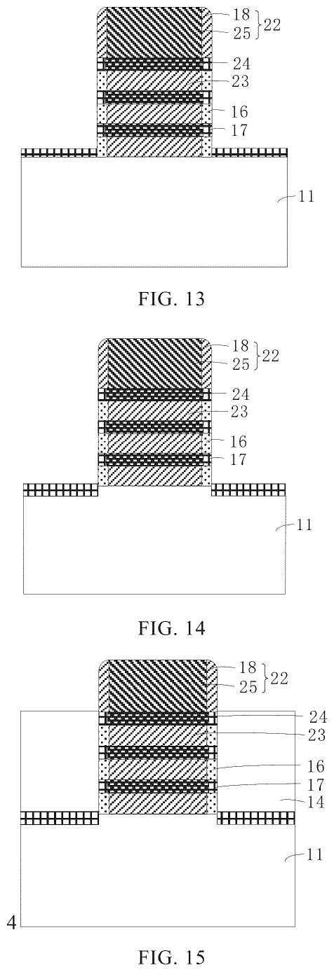

As for the conductive semiconductor structure disposed between the semiconductor base substrate and the source/drain region, as shown in FIG. 13, this portion of the conductive semiconductor structure 17 may be disposed on the semiconductor base substrate 11, that is, the bottom height of this portion of the conductive semiconductor structure 17 is equal to the bottom height of the gate stack structure 15. Alternatively, as shown in FIG. 18, in the conductive semiconductor structure 17 between the semiconductor base substrate 11 and the source/drain region 14, at least a portion of the region in the thickness direction of the semiconductor base substrate 11 may also be disposed within the semiconductor base substrate 11, and at this point, the source/drain region 14 with a high doping concentration has a larger formation range, which is beneficial for further improving the electrical performance of the gate-all-around transistor 12.

Regarding the material of the conductive semiconductor structure, the material may include any semiconductor material such as silicon, silicon-germanium, or germanium, as long as the material may be applied to the semiconductor device provided by the embodiments of the present invention.

Exemplarily, the material of the conductive semiconductor structure may be substantially the same as the material of the channel region.

Optionally, the material of the conductive semiconductor structure may include Si₁₋ₓGeₓ, and the material of the channel region may include Si_{1-y}Ge_{y}, where 0≤x ≤1, 0≤y≤1, and the absolute value of the difference between x and y is less than or equal to 0.3.

For example, when the material of the channel region includes silicon, the material of the conductive semiconductor structure may include Si_{0.7}Ge_{0.3}, Si_{0.75}Ge_{0.25}, Si_{0.8}Ge_{0.2}, Si_{0.85}Ge_{0.15}, or Si_{0.9}Ge_{0.1}, and the like.

Exemplarily, the material bandgap of the conductive semiconductor structure may be less than or equal to the material bandgap of the channel region. When the material bandgap of the conductive semiconductor structure is less than the material bandgap of the channel region, the series resistance of the conductive semiconductor structure may be further reduced, and meanwhile, the leakage risk between the source region and the drain region may be favorably suppressed.

In some cases, as shown in FIG. 6 and FIG. 18, the semiconductor device provided by the embodiments of the present invention may further include at least one of a shallow trench isolation structure 19 and an interlayer dielectric layer 20. The shallow trench isolation structure 19 is formed on the semiconductor base substrate 11 to define the active region of the semiconductor base substrate 11, which may reduce the leakage risk, and further improve the yield rate and working performance of the semiconductor device. The above-mentioned interlayer dielectric layer 20 covers the semiconductor base substrate 11, and the top of the interlayer dielectric layer 20 is flush with the top of the gate stack structure 15 to protect the source/drain region 14 from the etching and cleaning operations for removing the sacrificial gate 25 and the sacrificial layer 23, thereby improving the yield rate of the gate-all-around transistor.

As for the materials of the shallow trench isolation structure and the interlayer dielectric layer, the materials of the shallow trench isolation structure and the interlayer dielectric layer may include any insulating material such as silicon oxide, silicon nitride, or silicon oxynitride, which is not specifically limited here.

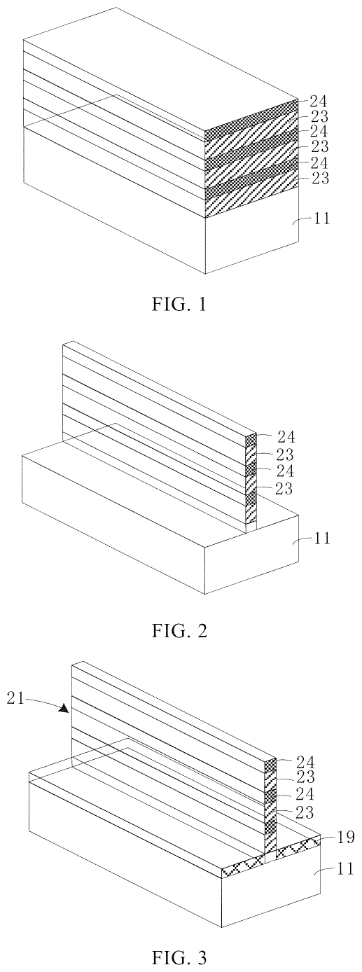

In a second aspect, the embodiments of the present invention provide a method of manufacturing a semiconductor device. The following describes the manufacturing process according to the perspective views or cross-sectional views of the operations shown in FIG. 1 to FIG. 18. Specifically, the method of manufacturing a semiconductor device includes the following steps.

First, a semiconductor base substrate is provided. The type of the semiconductor base substrate may be referred to the above description, which will not be described in detail here.

Next, as shown in FIG. 3 and FIG. 5, a fin-shaped structure 21 is formed on the semiconductor base substrate 11, and a mask structure 22 across the fin-shaped structure 21 is formed. The fin-shaped structure 21 includes at least one semiconductor stack, and each semiconductor stack includes a sacrificial layer 23 and a channel layer 24 on the sacrificial layer 23.

Specifically, the channel layer included in the above-mentioned fin-shaped structure is used to manufacture the nanostructure included in the channel region. Therefore, the number of layers of the channel layer included in the fin-shaped structure is equal to the number of layers of the nanostructure included in the channel region, and the material of the channel layer is the same as the material of the nanostructure included in the channel layer.

As for the sacrificial layer, the nanoscale structure included in the channel region will be released by subsequently removing a portion of the sacrificial layer. Therefore, the thickness of the sacrificial layer may be determined according to the spacing between different layers of nanostructures included in the channel region and the spacing between the nanostructures and the semiconductor base substrate in the actual application scenario. As for the material of the sacrificial layer, the material of the sacrificial layer may be any semiconductor material different from the material of the channel layer.

For example, when the material of the channel layer is silicon, the material of the sacrificial layer may be silicon-germanium or germanium.

As for the above-mentioned mask structure, the material of the mask structure may be set according to actual needs as long as the material of the mask structure may play a mask protection role in the follow-up process.

Exemplarily, as shown in FIG. 5, the mask structure 22 may include a sacrificial gate 25 and a gate spacer 18 located on both sides of the sacrificial gate 25 in the length direction. The material of the sacrificial gate 25 may include an easily removable material such as polycrystalline silicon. The material of the gate spacer 18 may be referred to the above description.

Exemplarily, the above-mentioned mask structure may also include a gate oxide layer, a sacrificial gate located on the gate oxide layer, and a gate spacer located on both sides of the sacrificial gate in the length direction. The material of the gate oxide layer may include a material such as silicon oxide.

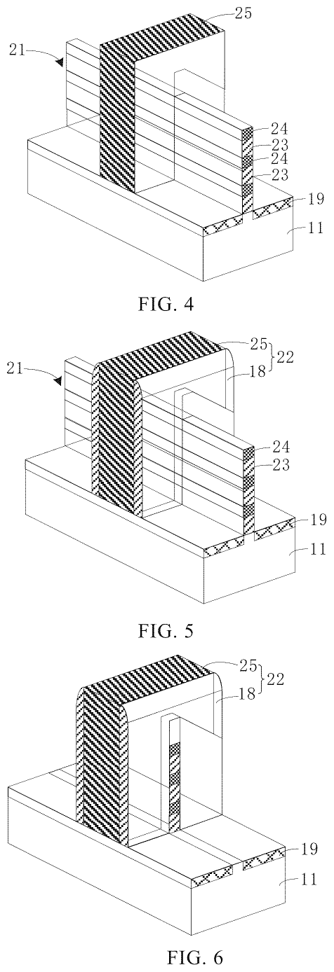

In the actual manufacturing process, as shown in FIG. 1, the sacrificial layer 23 and the channel layer 24 that are alternately stacked may be formed in the thickness direction of the semiconductor base substrate 11 by using a process such as epitaxy. Then, as shown in FIG. 2, the sacrificial layer 23, the channel layer 24, and a portion of the semiconductor base substrate 11 described above are patterned by using processes such as photolithography and etching to form a fin. Next, as shown in FIG. 3, a shallow trench isolation structure 19 for defining an active region may be formed between adjacent fins by using processes such as deposition and etching. The top height of the shallow trench isolation structure 19 is less than or equal to the bottom height of the sacrificial layer 23 located on the bottom layer. The portion of the fin exposed outside the shallow trench isolation structure 19 is the fin-shaped structure 21. Next, a mask material covering the semiconductor base substrate 11 may be formed by using a deposition process. Then, as shown in FIG. 4 and FIG. 5, the mask material is selectively etched by using processes such as photolithography and etching to form the above-mentioned mask structure 22.

It should be noted that when the manufactured semiconductor device does not include the above-mentioned shallow trench isolation structure, patterning may be performed only on the sacrificial layer and the channel layer. The fin-shaped structure may be directly obtained after the patterning process.

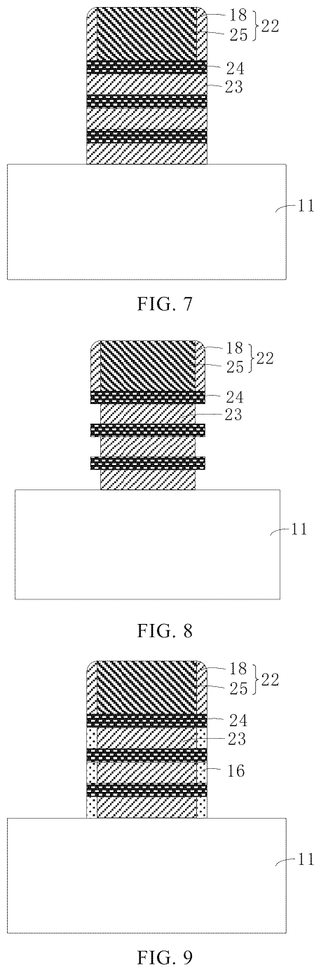

Next, as shown in FIG. 6 and FIG. 7, the portion of the fin-shaped structure exposed outside the mask structure 22 may be removed by using a process such as dry etching or wet etching.

Next, as shown in FIG. 8, the edge portions on both sides of the sacrificial layer 23 in the length direction may be etched and removed by using a process such as dry etching or wet etching; and as shown in FIG. 9, an inner spacer 16 is formed on both sides of the remaining sacrificial layer 23 by using deposition and etching processes. The material and width of the inner spacer 16 may be referred to the above description, which will not be described in detail here.

Next, as shown in FIG. 10 and FIG. 11, the edge portions on both sides of the channel layer 24 in the length direction may be etched and removed by using a process such as dry etching or wet etching; and as shown in FIG. 12 to FIG. 14, a conductive semiconductor structure 17 is formed at least on both sides of the remaining channel layer 24 by using at least a deposition process.

It is should be noted that, as shown in FIG. 8 to FIG. 14, in the method of manufacturing a semiconductor device provided by the embodiments of the present invention, although both sides of the channel layer 24 in the length direction are still exposed and etching damage is still present at the edge portions thereof in the process of forming the inner spacer 16, before epitaxially forming the source/drain region 14, the edge portions on both sides of the channel layer 24 in the length direction are etched and removed, and the conductive semiconductor structure 17 with higher crystal quality and better conductivity is formed, which is beneficial for improving the electrical performance of the gate-all-around transistor 12. The material, width, conductive type, and other conditions of the conductive semiconductor structure 17 may be referred to the above description, which will not be described in detail here.

It should be noted that during the formation of the conductive semiconductor structure, the conductive semiconductor structure may be formed only on both sides of the remaining channel layer. Alternatively, the conductive semiconductor structure may be formed on both sides of the remaining channel layer and on the semiconductor base substrate.

In addition, in a case that in the manufactured semiconductor device, the conductive semiconductor structure disposed between the channel region and the source/drain region is only disposed below the gate spacer, as shown in FIG. 12 to FIG. 14, it is further necessary to selectively etch the conductive semiconductor structure 17 by using a process such as dry etching or wet etching under the protection of the mask structure 22. After the above-mentioned selective etching, the sidewall of the conductive semiconductor structure 17 disposed on both sides of the remaining channel layer 24 facing away from the channel layer 24 may be aligned with the sidewall of the inner spacer 16 facing away from the gate stack structure 15, or may be recessed inward relative to the sidewall of the inner spacer 16 facing away from the gate stack structure 15.

In addition, as shown in FIG. 11, in the actual manufacturing process, while etching and removing the edge portions on both sides of the channel layer 24 in the length direction, a partial thickness of the semiconductor base substrate 11 may also be etched to facilitate obtaining the source/drain region 14 with a larger formation range. When the material of the channel layer 24 is substantially the same as the material of the semiconductor base substrate 11, the etching steps may be performed simultaneously. When the materials of the channel layer 24 and the semiconductor base substrate 11 are different, the etching operation corresponding to the channel layer 24 and the etching operation corresponding to the semiconductor base substrate 11 may be performed in separate steps.

Next, as shown in FIG. 15, the source/drain region 14 is epitaxially formed.

Optionally, the conductive semiconductor structure and the source/drain region may be sequentially formed in the same vacuum epitaxy chamber to prevent the formed structure from being exposed to the external environment and affecting the yield rate of the formed structure in the process of transferring the formed structure between different chambers after forming the conductive semiconductor structure and before forming the source/drain region.

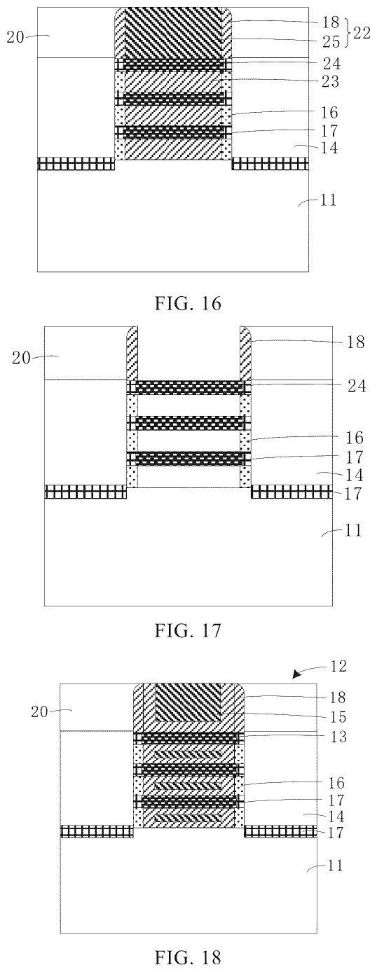

Next, as shown in FIG. 16, an interlayer dielectric layer 20 covering the semiconductor base substrate 11 is formed by using processes such as deposition and planarization. The top of the interlayer dielectric layer 20 is flush with the top of the mask structure 22. The material of the interlayer dielectric layer 20 may be referred to the above description, which will not be described in detail here.

Next, as shown in FIG. 17 and FIG. 18, a gate stack structure 15 surrounding the periphery of the remaining channel layer is formed to obtain a gate-all-around transistor 12.

In the actual manufacturing process, as shown in FIG. 17, at least a portion of the mask structure and the remaining sacrificial layer may be removed by using a process such as dry etching or wet etching to release the remaining channel layer 24. Then, as shown in FIG. 18, the gate stack structure 15 may be formed by using an atomic layer deposition process.

The specific structure and material of the gate stack structure may be referred to the above description, which will not be described in detail here.

The beneficial effects of the second aspect and various implementations thereof in the embodiments of the present invention may refer to the analysis of the beneficial effects of the first aspect and various implementations thereof, which will not be described in detail here.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely the same as the method described above. Furthermore, although the various embodiments are described above separately, this does not mean that the measures in the various embodiments may not be advantageously used in combination.

The embodiments of the present invention have been described above. However, these embodiments are for clarity of illustration only, and are not intended to limit the scope of the present invention. The scope of the present invention is defined by the appended claims and their equivalents. Without departing from the scope of the present invention, those skilled in the art may make various substitutions and modifications, and these substitutions and modifications should all fall within the scope of the present invention.

What is claimed is:

1. A semiconductor device comprising: a semiconductor base substrate, and a gate-all-around transistor disposed on the semiconductor base substrate, wherein the gate-all-around transistor comprises a channel region, a source/drain region, a gate stack structure, an inner spacer, and a conductive semiconductor structure;
the source/drain region is disposed on both sides of the channel region in a length direction;
the gate stack structure surrounds a periphery of the channel region;
the inner spacer is disposed between the gate stack structure and the source/drain region; and
the conductive semiconductor structure is disposed at least between the channel region and the source/drain region, at least a partial region of the conductive semiconductor structure overlaps with at least a partial region of the inner spacer in a length direction of the gate stack structure, and an interface is disposed between the conductive semiconductor structure and the channel region.

2. The semiconductor device according to claim 1, wherein a conductivity type of the conductive semiconductor structure is the same as a conductivity type of the source/drain region; and/or
a doping concentration of the conductive semiconductor structure is greater than or equal to 1 E18 cm⁻³ and less than or equal to 5 E19 cm⁻³; and/or
a doping concentration of the conductive semiconductor structure is less than a doping concentration of the source/drain region.

3. The semiconductor device according to claim 1, wherein a material bandgap of the conductive semiconductor structure is less than or equal to a material bandgap of the channel region.

4. The semiconductor device according to claim 1, wherein a width of the conductive semiconductor structure disposed on both sides of the channel region in the length direction of the gate stack structure is less than a width of the inner spacer; and/or
a sidewall of the conductive semiconductor structure disposed on both sides of the channel region facing away from the channel region is aligned with a sidewall of the inner spacer facing away from the gate stack structure.

5. The semiconductor device according to claim 1, wherein a material of the conductive semiconductor structure is the same as a material of the channel region; and/or
a material of the conductive semiconductor structure comprises Si₁₋ₓGeₓ, and a material of the channel region comprises Si_{1-y}Ge_{y}, wherein 0≤x≤1, 0≤y≤1, and an absolute value of a difference between x and y is less than or equal to 0.3.

6. The semiconductor device according to claim 1, wherein the conductive semiconductor structure is further disposed between the semiconductor base substrate and the source/drain region.

7. The semiconductor device according to claim 6, wherein in the conductive semiconductor structure disposed between the semiconductor base substrate and the source/drain region, at least a partial region in a thickness direction of the semiconductor base substrate is disposed within the semiconductor base substrate.

8. The semiconductor device according to claim 1, wherein the gate-all-around transistor further comprises a gate spacer disposed at least on both sides of the gate stack structure in a length direction;
a sidewall of the channel region is recessed inward relative to a sidewall of the gate spacer in a direction in which the source/drain region approaches the channel region.

9. A method of manufacturing a semiconductor device, comprising:
providing a semiconductor base substrate;
forming a fin-shaped structure on the semiconductor base substrate and forming a mask structure across the fin-shaped structure, wherein the fin-shaped structure comprises at least one semiconductor stack, and each semiconductor stack comprises a sacrificial layer and a channel layer located on the sacrificial layer;
removing a portion of the fin-shaped structure exposed outside the mask structure;
etching and removing edge portions on both sides of the sacrificial layer in a length direction; and forming an inner spacer on both sides of the remaining sacrificial layer;
etching and removing edge portions on both sides of the channel layer in a length direction; and forming a conductive semiconductor structure at least on both sides of the remaining channel layer; and
epitaxially forming a source/drain region; and forming a gate stack structure surrounding a periphery of the remaining channel layer to obtain a gate-all-around transistor.

10. The method of manufacturing a semiconductor device according to claim 9, wherein the mask structure comprises a sacrificial gate, and a gate spacer located on both sides of the sacrificial gate in a length direction.

11. The method of manufacturing a semiconductor device according to claim 9, wherein a partial thickness of the semiconductor base substrate is etched while etching and removing edge portions on both sides of the channel layer in the length direction.

12. The method of manufacturing a semiconductor device according to claim 9, wherein after forming the conductive semiconductor structure on both sides of the remaining channel layer and on the semiconductor base substrate and before the epitaxially forming a source/drain region, the method of manufacturing a semiconductor device further comprises:
under a protection of the mask structure, selectively etching the conductive semiconductor structure such that a sidewall of the conductive semiconductor structure disposed on both sides of the remaining channel layer facing away from the channel layer is aligned with a sidewall of the inner spacer facing away from the gate stack structure.

13. That method of manufacture a semiconductor device accord to claim 9, wherein the forming a conductive semiconductor structure at least on both sides of the remaining channel layer comprises: forming the conductive semiconductor structure on both sides of the remaining channel layer and on the semiconductor base substrate.

14. The method of manufacturing a semiconductor device according to claim 9, wherein the conductive semiconductor structure and the source/drain region are sequentially formed within a same vacuum epitaxial chamber.
